(19) United States
(12) Patent Application Publication
(10) Pub. No.: US 2011/0079285 A1
(43) Pub. Date: Apr. 7, 2011

(54) POLYMER SOLAR CELL AND MANUFACTURING METHOD THEREOF

(75) Inventors: Fang-Chung Chen, Nantou County (TW); Shang-Chieh Chien, Taipei County (TW)

(73) Assignee: National Chiao Tung University, Hsinchu City (TW)

(21) Appl. No.: 12/647,546

(22) Filed: Dec. 28, 2009

(30) Foreign Application Priority Data
Oct. 5, 2009 (TW) 98133688

(51) Int. Cl. H01L 31/0256; H01L 31/18

(52) U.S. Cl. 136/263; 438/82; 257/E31.001; 257/E31.003

(57) ABSTRACT

A manufacturing method of a polymer solar cell is illustrated. A substrate and a first conductive layer formed thereon are provided. An organic active semiconductor material and a functional organic material, which features modifying an interface between an organic layer and electrodes, are dissolved in an organic solvent to form a blend. The blend is deposited on the first conductive layer by solution process. The organic solvent is removed, such that the functional organic material and the organic active semiconductor material exhibit phase separation so as to form an organic modified layer on the top of the organic active semiconductor layer. A second conductive layer is deposited by thermal coating on the organic modified layer. Importantly, the organic modified layer formed by spontaneous phase separation effectively modifies the interface between the organic active semiconductor layer and a second conductive layer, thereby enhancing efficiency of an organic solar cell.

### CROSS-REFERENCE TO RELATED APPLICATION

This application claims the priority benefit of Taiwan application serial no. 98133688, filed on Oct. 5, 2009. The entirety of the above-mentioned patent application is hereby incorporated by reference herein and made a part of specification.

### BACKGROUND OF THE INVENTION

1. Field of the Invention

The invention relates to a solar cell and a manufacturing method thereof. In particular, the invention relates to a polymer solar cell and a manufacturing method thereof.

2. Description of Related Art

As environmental problems such as costly energy source and global warming receive more attention, the development of solar cells has also gradually become more essential. Currently, most of commercialized solar cells are manufactured based on silicon semiconductor material. Generally speaking, solar cells can be categorized into monocrystalline silicon, polycrystalline silicon, amorphous silicon, and so on according to the lattice type of silicon. Monocrystalline silicon solar cells feature excellent and stable energy conversion efficiency; however, the manufacturing cost is relatively high. On the other hand, amorphous silicon devices have lower efficiency and shorter lifetime. In consideration of price, although cheaper than monocrystalline silicon solar cells, amorphous silicon devices are still much more expensive than general household electricity cost.

Recently, solar cells manufactured based on organic materials such as polymers and the like have gradually obtained more attention from considerable research organizations and the technical industries. Polymer solar cells are manufactured based on polymer materials having features similar to plastics; meanwhile, polymer solar cells can be manufactured on flexible plastics substrate, glass substrate, or thin metal substrates. Therefore, polymer solar cells have light weight and superior flexibility, are breakage resistant and impact resistant, and have low manufacturing costs.

However, in conventional organic solar cells, metal materials that have high work function and are not easily oxidized in the ambient are used as cathode metal layers. Moreover, due to high work function, a large barrier-height is existed between the cathode metal layer and the organic active semiconductor layer, such that electrons formed in the organic active semiconductor layer are not favored in passing over the energy barrier so as to be collected by the cathode to form a photocurrent. Therefore, conventionally, in order to efficiently enhance the power conversion efficiency (PCE) and open circuit voltage (V_{oc}) of organic solar cells, a metal layer (or alkali metal complex layer) with low work function is additionally formed on the organic active semiconductor layer as a modified layer between the organic semiconductor active layer the cathode metal layer, thereby effectively improving the electron collection property. Nevertheless, the metal layer with low work-function is easily oxidized in the atmosphere and alkali metal complex (i.e. lithium fluoride, cesium carbonate, cesium fluoride) is easily hydrolyzed, thereby causing deterioration of devices so as to greatly shorten the device operating stability of the organic solar cell. Furthermore, extra fabrication processes such as thermal evaporation and spin coating both require an additional costs, so that manufacturing costs in the subsequent mass production increase greatly.

### SUMMARY OF THE INVENTION

The invention is directly related to a method of manufacturing a polymer solar cell. The method includes fewer processing steps, is more simple, and is capable of obtaining a solar power device with high efficiency.

The invention is directed to a superior polymer solar cell performance with a long operation lifetime.

The invention is directed to a method of manufacturing a polymer solar cell. The manufacturing method is illustrated below. Firstly, a substrate is provided. Next, a first conductive layer is formed on the substrate. Then, an organic active semiconductor material and a functional organic material are dissolved in an organic solvent so as to form a blend. Afterwards, the blend is disposed on the first conductive layer. The organic solvent is subsequently removed, such that the functional organic material and the organic active semiconductor material exhibit a phase separation so that the functional organic material is spontaneously formed on the organic active semiconductor layer to form an organic active semiconductor layer and an organic modified layer. Here, the organic active semiconductor layer is sandwiched between the organic modified layer and the first conductive layer. Thereafter, a second conductive layer is formed on the organic modified layer.

According to an embodiment of the invention, the weight concentration of the functional organic material in the blend is less than 30 wt % of the blend.

According to an embodiment of the invention, the weight concentration of the functional organic material in the blend is substantially 5 wt % of the blend.

According to an embodiment of the invention, a method of disposing the blend on the first conductive layer includes spin coating, inkjet-printing, screen-printing, doctor-blade coating and spray-coating. According to an embodiment of the invention, the functional organic material includes organic materials such as polyethylene glycol, poly(methylmethacrylate) (PMMA), polystyrene (PS), or poly(ethylene oxide) (PEO).

According to an embodiment of the invention, the organic active semiconductor material includes a mixed semiconductor material constituting an n-type semiconductor material and a p-type semiconductor material.

According to an embodiment of the invention, the n-type semiconductor material includes [6,6]-phenyl-C61-butyric acid methyl ester (PCBM), and the p-type semiconductor material includes poly(3-hexylthiophene) (P3HT).

According to an embodiment of the invention, a material of the second conductive layer includes a material with high work function.

According to an embodiment of the invention, a material of the second conductive layer includes aluminum, gold, silver, or copper.

According to an embodiment of the invention, a method of forming the second conductive layer includes thermal evaporation. According to an embodiment of the invention, a method of removing the organic solvent includes evaporating the organic solvent.

According to an embodiment of the invention, a method of forming the first conductive layer includes forming an electrode layer on the substrate and forming a conductive polymer layer on the electrode layer. According to an embodiment of the invention, a material of the electrode layer includes indium tin oxide (ITO) or indium zinc oxide (IZO).

The invention is directed to a polymer solar cell including a substrate, a first conductive layer, an organic active semiconductor layer, an organic modified layer, and a second conductive layer. The first conductive layer is deposited on the substrate. The organic active semiconductor layer is disposed on the first conductive layer. The organic modified layer is disposed on the organic active semiconductor layer and a material of the organic modified layer includes polymer oxide such as polyethylene glycol and the like. The second conductive layer is disposed on the organic modified layer.

According to an embodiment of the invention, a material of the organic active semiconductor layer includes an n-type semiconductor material and a p-type semiconductor material.

According to an embodiment of the invention, the n-type semiconductor material includes [6,6]-phenyl-C61-butyric acid methyl ester (PCBM), and the p-type semiconductor material includes poly(3-hexylthiophene) (P3HT).

According to an embodiment of the invention, a material of the second conductive layer includes a material with high work function.

According to an embodiment of the invention, a material of the second conductive layer includes aluminum, gold, silver, or copper.

According to an embodiment of the invention, the first conductive layer includes an electrode layer and a conductive polymer layer. Herein, the electrode layer is deposited between the substrate and the conductive polymer layer.

According to an embodiment of the invention, a material of the electrode layer includes ITO or IZO.

In light of the foregoing, in the invention, the functional organic material and the organic active semiconductor material that generate a phase separation are blended and formed on the first conductive layer. The organic active semiconductor layer and the organic modified layer are formed respectively through the phase separation generated by the functional organic material and the organic active semiconductor material. Hence, the manufacturing method of the invention does not require an extra process to form the modified layer. The processing steps can therefore be simplified, thereby reducing the manufacturing cost.

In order to make the aforementioned and other features and advantages of the invention more comprehensible, several embodiments accompanied with drawings are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A˜1D illustrate the cross-sectional view of a process of manufacturing a polymer solar cell according to an embodiment of the invention.

FIG. 2 illustrates the current-voltage characteristic diagram of a polymer solar cell of an embodiment of the invention and a polymer solar cell in a comparative example. FIG. 2 shows the comparison of the polymer solar cells before and after blending the addition of 5 wt. % PEG.

FIG. 3 illustrates the changes of short-circuit currents of a polymer solar cell of an embodiment of the invention and polymer solar cells in comparative examples with respect to operation time. In particular, FIG. 3 reveals that the time-dependent photocurrent of the Al-cathode device under illumination was comparable to those of conventional devices prepared using Ca/Al and LiF/Al as cathode structures.

### DESCRIPTION OF EMBODIMENTS

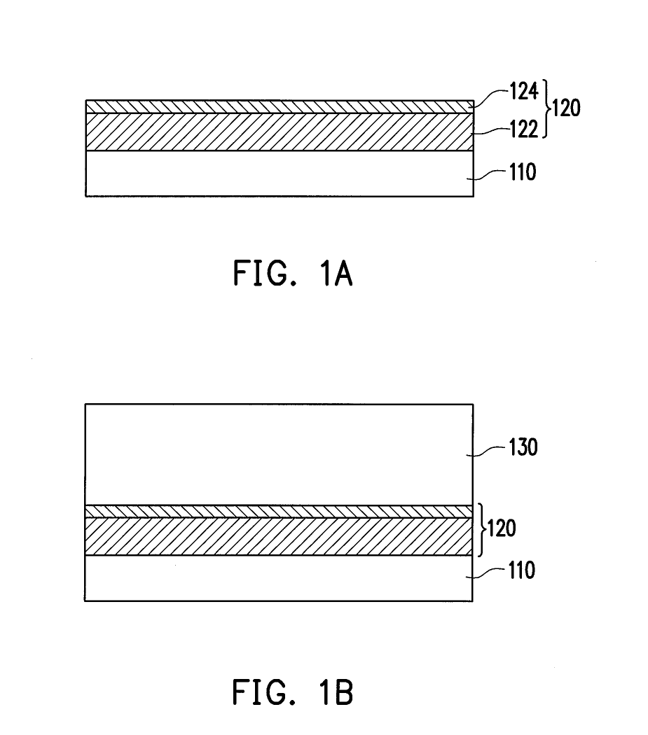

FIGS. 1A˜4D illustrate a cross-sectional view of a process of manufacturing a polymer solar cell according to an embodiment of the invention.

Firstly, referring to FIG. 1A, a substrate 110 is provided. Next, a first conductive layer 120 is formed on the substrate 110. In details, the first conductive layer 120 is formed by the following method. Firstly, an electrode layer 122 is formed on the substrate 110 and a conductive polymer layer 124 is formed on the electrode layer 122. The electrode layer 122 is made of indium tin oxide (ITO) or indium zinc oxide (IZO), for example.

Referring to FIG. 1B, an organic active semiconductor material (not shown) and a functional organic material (not shown) are dissolved in an organic solvent (not shown) so as to form a blend 130. Afterwards, the blend 130 is disposed on the first conductive layer 120 by spin coating process. In the present embodiment, the functional organic material occupies less than 30 wt % of the blend 130. For instance, the functional organic material occupies 5 wt % of the blend 130.

In the present embodiment, the functional organic material includes polyethylene glycol (PEG), poly(methyl methacrylate) (PMMA), polystyrene (PS), poly(ethylene oxide) (PEO), or other materials adapted for generating vertical phase separation with the organic active semiconductor material. Here, a molecular weight of PEG ranges from 100˜8000, more specifically, the molecular weight of PEG ranges from 100˜3000. In the present embodiment, the organic active semiconductor material includes a mixed semiconductor material constituted by an n-type semiconductor material and a p-type semiconductor material. The n-type semiconductor material includes [6,6]-phenyl-C61-butyric acid methyl ester (PCBM) and the p-type semiconductor material includes poly(3-hexylthiophene) (P3HT). In the present embodiment, the organic solvent includes dichlorobenzene, chlorobenzene, toluene, chloroform, tetrahydrofuran, and trichlorobenzene.

Referring to FIG. 1C, the organic solvent was removed by evaporation, for example, such that the functional organic material and the organic active semiconductor material exhibit a phase separation so as to form an organic active semiconductor layer 132 and an organic modified layer 134. The organic active semiconductor layer 132 is sandwiched between the organic modified layer 134 and the first conductive layer 120. Specifically, in the present embodiment, the organic active semiconductor layer 132 is mainly constituted by the organic active semiconductor material, and the organic modified layer 134 is mainly constituted by the functional organic material.

Referring to FIG. 1D, a second conductive layer 140 is formed on the organic modified layer 134 by thermal evaporation, for instance. In the present embodiment, the second conductive layer 140 is made of a material with high work function. For example, the second conductive layer 140 is made of a material with superior conductivity such as aluminum, gold, silver, or copper. Up to this point, a polymer solar cell 100 is preliminarily formed.

It should be noted that in the present embodiment, the functional organic material and the organic active semiconductor material that generate the phase separation are dissolved in the organic solvent to form the blend 130 and coated on the first conductive layer 120. The organic solvent is then removed such that the phase separation between the functional organic material and the organic active semiconductor material is generated. The organic active semiconductor layer 132 and the organic modified layer 134 are formed respectively as a result. Hence, the manufacturing method of the present embodiment does not require an extra process for forming the organic modified layer 134. The processing steps can therefore be simplified.

Moreover, the polymer solar cell 100 of the present embodiment has the functional organic material (i.e. PEG, PMMA, PS, or PEO) stably present in the atmosphere and capable of replacing conventional low work function metals that are easily oxidized and alkali metal complexes that are easily hydrolyzed. Thus, the polymer solar cell 100 of the present embodiment has a longer device operating lifetime when exposed and operating under simulated sunlight (100 mW/cm²).

A structure of the polymer solar cell 100 is depicted in details hereinafter.

Referring to FIG. 1D, the polymer solar cell 100 of the present embodiment includes a substrate 110, a first conductive layer 120, an organic active semiconductor layer 132, an organic modified layer 134, and a second conductive layer 140. The first conductive layer 120 is deposited on the substrate 110. In details, in the present embodiment, the first conductive layer 120 includes an electrode layer 122 and a conductive polymer layer 124. Herein, the electrode layer 122 is deposited between the substrate 110 and the conductive polymer layer 124.

The organic active semiconductor layer 132 is deposited on the first conductive layer 120. The organic modified layer 134 is deposited on the organic active semiconductor layer 132 and the organic modified layer 134 is composed of PEG. The second conductive layer 140 is deposited on the organic modified layer 134.

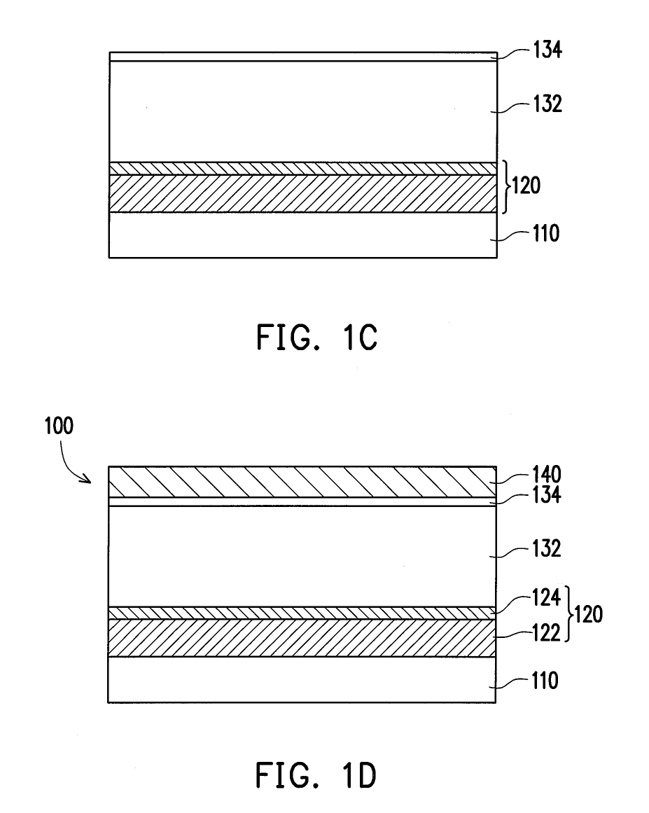

FIG. 2 illustrates a current-voltage characteristic diagram of a polymer solar cell of an embodiment of the invention and a polymer solar cell in a comparative example. FIG. 2 shows the comparison of the polymer solar cells before and after blending the addition of 5 wt. % PEG.

The polymer solar cell 100 measured in FIG. 2 has an organic modified layer 134 manufactured of 5 wt % of PEG (relative to the total weight of the blend). On the other hand, the solar cell in the comparative example does not include an organic modified layer. As illustrated in FIG. 2, the organic modified layer 134 of the present embodiment greatly enhances a power conversion efficiency of the polymer solar cell 100.

In specific, comparing to the solar cell having an open circuit voltage of 0.49 V and a short-circuit current of 8.4 mA/cm² in the comparative example, the polymer solar cell 100 of the present embodiment has an enhanced opening circuit voltage of 0.59 V and an enhanced short-circuit current of 12.1 mA/cm². In addition, comparing to the solar cell having a power conversion efficiency of 2.32% in the comparative example, the polymer solar cell 100 of the present embodiment has a power conversion efficiency of 3.97%. Accordingly, the organic modified layer 134 facilitates electrons in the organic active semiconductor layer 132 to pass through the energy barrier between the organic active semiconductor layer 132 and the second conductive layer 140 more easily so as to be received by the second conductive layer 140.

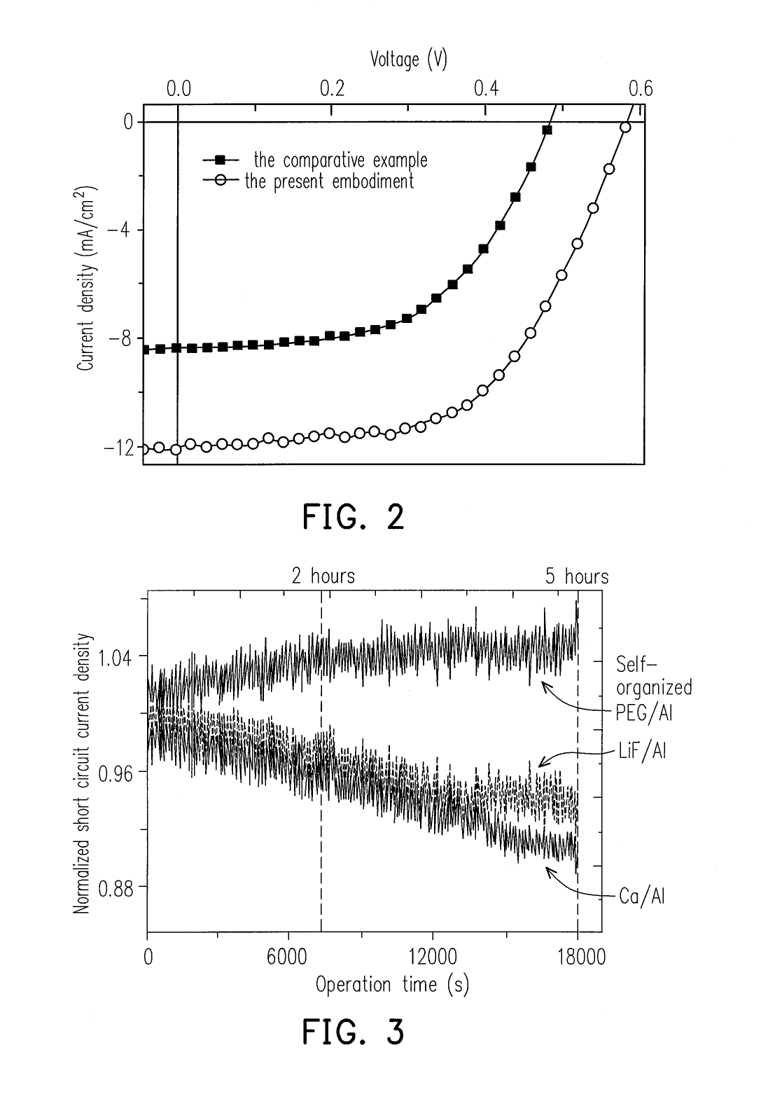

FIG. 3 illustrates changes of short-circuit currents of a polymer solar cell of an embodiment of the invention and polymer solar cells in comparative examples with respect to operation time (second).

The polymer solar cell 100 measured in FIG. 3 has an organic modified layer 134 manufactured of 5 wt % of PEG (relative to the total weight of the blend) and a second conductive layer 140 made of aluminum. The polymer solar cell 100 is notated as self-organized PEG/Al in FIG. 3 and Table 1. Further, two solar cells are measured as comparative examples in FIG. 3. In one comparative example, the solar cell is a solar cell adopting lithium fluoride as the modified layer and adopting aluminum as the second conductive layer (the solar cell is notated as LiF/Al in FIG. 3 and Table 1). In the other comparative example, the solar cell is a solar cell adopting calcium as the modified layer and adopting aluminum as the second conductive layer (the solar cell is notated as Ca/Al in FIG. 3 and Table 1).

FIG. 3 illustrates changes of short-circuit currents of the polymer solar cell 100 of the present embodiment and polymer solar cells in comparative examples with respect to an operation time (5 hours in total) under a simulated sunlight of 100 mW/cm².

Table 1 illustrates power conversion efficiencies of the polymer solar cell 100 of the present embodiment and the solar cells in the comparative examples before exposure and power conversion efficiencies of the polymer solar cell 100 of the present embodiment and the solar cells in the comparative examples after a 5 hour exposure under an illumination of 100 mW/cm².

TABLE 1

| | Self-organized PEG/Al | LiF/Al | Ca/Al |
|---|---|---|---|
| Before exposure | 3.97% | 2.92% | 3.60% |
| After exposure | 4.24% | 2.27% | 2.98% |
| (5 hr) | | | |

As shown in FIG. 3 and Table 1, compared to the short-circuit currents of the solar cells in the comparative examples which decrease along with an increase in operation time so as to result in a great reduction of the power conversion efficiencies, the short-circuit current and power conversion efficiency of the polymer solar cell 100 of the present embodiment remain steady with the increase in operation time. Accordingly, the polymer solar cell 100 of the present embodiment has a longer device lifetime.

In summary, in the invention, the functional organic material and the organic active semiconductor material are blended and formed on the first conductive layer, and then generate a phase separation. The organic active semiconductor layer and the organic modified layer are formed respectively through the phase separation generated by the functional organic material and the organic active semiconductor material. Hence, the manufacturing method of the invention does not require an extra process to form the modified layer. The processing steps of organic solar cells can therefore be simplified. Furthermore, the organic modified layer of the invention greatly enhances the power conversion efficiency and the device operating lifetime of the polymer solar cell.

Although the invention has been described with reference to the above embodiments, it is apparent to one of ordinary skill in the art that modifications to the described embodiments may be made without departing from the spirit of the invention. Accordingly, the scope of the invention is defined by the attached claims not by the above detailed descriptions.

What is claimed is:

1. A method of manufacturing a polymer solar cell, comprising:
providing a substrate;
forming a first conductive layer on the substrate;
dissolving an organic active semiconductor material and a functional organic material in an organic solvent so as to form a blend;
depositing the blend on the first conductive layer;
removing the organic solvent, such that the functional organic material and the organic active semiconductor material exhibit a phase separation so as to form an organic modified layer and an organic active semiconductor layer, wherein the organic active semiconductor layer is sandwiched between the organic modified layer and the first conductive layer; and
forming a second conductive layer on the organic modified layer.

2. The method of manufacturing the polymer solar cell as claimed in claim 1, wherein a content of the functional organic material in the blend is less than 30 wt % of the blend.

3. The method of manufacturing the polymer solar cell as claimed in claim 2, wherein a content of the functional organic material in the blend is substantially 5 wt % of the blend.

4. The method of manufacturing the polymer solar cell as claimed in claim 1, wherein a method of disposing the blend on the first conductive layer comprises spin coating, inkjet-printing, screen-printing, doctor-blade coating and spray-coating.

5. The method of manufacturing the polymer solar cell as claimed in claim 1, wherein the functional organic material comprises polyethylene glycol, poly(methyl methacrylate, polystyrene, or poly(ethylene oxide).

6. The method of manufacturing the polymer solar cell as claimed in claim 1, wherein the organic active semiconductor material comprises a mixed semiconductor material constituted by an n-type semiconductor material and a p-type semiconductor material.

7. The method of manufacturing the polymer solar cell as claimed in claim 6, wherein the n-type semiconductor material comprises [6,6]-phenyl-C61-butyric acid methyl ester, and the p-type semiconductor material comprises poly(3-hexylthiophene).

8. The method of manufacturing the polymer solar cell as claimed in claim 1, wherein a material of the second conductive layer comprises a material featuring high work function.

9. The method of manufacturing the polymer solar cell as claimed in claim 8, wherein a material of the second conductive layer comprises aluminum, gold, silver, or copper.

10. The method of manufacturing the polymer solar cell as claimed in claim wherein a method of forming the second conductive layer comprises evaporation.

11. The method of manufacturing the polymer solar cell as claimed in claim wherein a method of removing the organic solvent comprises evaporating the organic solvent.

12. The method of manufacturing the polymer solar cell as claimed in claim 1, wherein a method of forming the first conductive layer comprises:
forming an electrode layer on the substrate; and
forming a conductive polymer layer on the electrode layer.

13. The method of manufacturing the polymer solar cell as claimed in claim 12, wherein a material of the electrode layer comprises indium tin oxide or indium zinc oxide.

14. A polymer solar cell, comprising:
a substrate;
a first conductive layer, deposited on the substrate;
an organic active semiconductor layer, deposited on the first conductive layer;
an organic modified layer, deposited on the organic active semiconductor layer and a material of the organic modified layer comprises polyethylene glycol; and
a second conductive layer, deposited on the organic modified layer.

15. The polymer solar cell as claimed in claim 14, wherein a material of the organic active semiconductor layer comprises an n-type semiconductor material and a p-type semiconductor material.

16. The polymer solar cell as claimed in claim 15, wherein the n-type semiconductor material comprises [6,6]-phenyl-C61-butyric acid methyl ester, and the p-type semiconductor material comprises poly(3-hexylthiophene).

17. The polymer solar cell as claimed in claim 14, wherein a material of the second conductive layer comprises a material having high work function.

18. The polymer solar cell as claimed in claim 17, wherein a material of the second conductive layer comprises aluminum, gold, silver, or copper.

19. The polymer solar cell as claimed in claim 14, wherein the first conductive layer comprises:
an electrode layer; and
a conductive polymer layer, wherein the electrode layer is sandwiched between the substrate and the conductive polymer layer.

20. The polymer solar cell as claimed in claim 19, wherein a material of the electrode layer comprises indium tin oxide or indium zinc oxide.
